(19) United States
(12) Patent Application Publication
(10) Pub. No.: US 2022/0070338 A1
(43) Pub. Date: Mar. 3, 2022

(54) IMAGING MODULE

(71) Applicant: Ningbo Semiconductor International Corporation, Ningbo, Zhejiang (CN)

(72) Inventor: Luo GUI, Ningbo, Zhejiang (CN)

(73) Assignee: Ningbo Semiconductor International Corporation, Ningbo, Zhejiang (CN)

(21) Appl. No.: 17/415,022

(22) PCT Filed: Jul. 1, 2020
(86) PCT No.: PCT/CN2020/099641

§ 371 Date: Jun. 17, 2021

(30) Foreign Application Priority Data
Nov. 20, 2019 (CN) 201911144081.1

(51) Int. Cl. H04N 5/225; G03B 5/02

(52) U.S. Cl. CPC H04N 5/2253; G03B 2205/0061; G03B 5/02; H04N 5/2254

(57) ABSTRACT

An imaging module, including a moved element; a limiting groove, arranged on a surface of the moved element; a piezoelectric element, including a movable end and a fixed end, wherein the movable end is provided with a rotating shaft, the rotating shaft is arranged in the limiting groove, the limiting groove provides a mobile space for the rotating shaft, and the movable end drives the moved element; an elastic limiting piece, one end of which is connected to the movable end of the piezoelectric element and the other end is located in the limiting groove or connected to a portion opposite to an end face of the movable end; a supporting block, configured to support and fix the piezoelectric element; and an external signal connection end, electrically connected to an electrode in the piezoelectric element.

### FIELD OF TECHNOLOGY

The present disclosure relates to the technical field of motion control, in particular to an imaging module.

### BACKGROUND

In some electronic terminals, it is usually necessary to translate, vertically move or incline some parts of the electronic terminals so as to realize some special functions. For example, at present, in various electronic terminals such as video cameras, cameras and mobile phones with lens modules, a movable lens or image sensor may generate displacement in an optic axis direction for focusing or zooming, or generate displacement in a direction vertical to the optic axis direction to prevent optical jittering usually through driving mechanisms such as a voice coil actuator/voice coil motor (VCM), etc. However, different form the traditional single lens reflex camera, it is a great engineering challenge to realize the function in the electronic terminals with narrow space, such as mobile phone, mini video cameras, cameras, etc. Therefore, a motion control structure is expected, such that the moved part moves according to an ideal state.

### SUMMARY

An objective of the present disclosure is to provide an imaging module, which can utilize the electrostriction effect of the piezoelectric element to control the moved element to move along a predetermined direction and is beneficial to reducing occupied space.

To achieve the above objective, the present disclosure provides an imaging module, including:
a moved element, including a lens group, an imaging sensing element, or an aperture, a reflector, or a lens;
a limiting groove, arranged on a surface of the moved element;
a piezoelectric element, including a movable end and a fixed end, wherein the movable end is provided with a rotating shaft, the rotating shaft is arranged in the limiting groove, the limiting groove provides a mobile space for the rotating shaft, and the movable end drives the moved element to move upwards or downwards when the piezoelectric element in a power-on state;
an elastic limiting piece, one end of which is connected to the movable end of the piezoelectric element and the other end is located in the limiting groove or connected to a portion opposite to an end face of the movable end, wherein the elastic limiting piece is in a free state when the piezoelectric element is in a free state, and the elastic limiting piece is compressed or stretched when the movable end of the piezoelectric element is warped;
a supporting block, configured to support and fix the piezoelectric element, wherein the fixed end is fixed at the supporting block; and
an external signal connection end, electrically connected to an electrode in the piezoelectric element.

In conclusion, a limiting groove is formed in the surface of the moved element, the fixed end of the piezoelectric element is fixed by the supporting block, the movable end is provided with the rotating shaft, the rotating shaft is located in the limiting groove, the elastic limiting piece is arranged in the limiting groove, the elastic limiting piece may reduce sliding of the rotating shaft in the limiting groove to prevent the moved element from moving in a non-required direction, so that the moving requirement of the moved element may be met; moreover, as compared with the traditional driving mechanism such as the VCM and the like, the combination of the piezoelectric element and the supporting block is lightweight, small in volume and simple in structure, can realize multi-dimensional motion and is suitable for the imaging module with narrow space volume, and the piezoelectric element is driven by pure voltage without electromagnetic interference.

### BRIEF DESCRIPTION OF THE DRAWINGS

FIG. 1A is a schematic diagram of an imaging module according to an embodiment of the present disclosure.

FIG. 1B is a sectional view of FIG. 1A along a cutting line A-A′.

FIG. 2 is a partial schematic diagram of an imaging module according to an embodiment of the present disclosure.

FIG. 3 is a schematic diagram of a piezoelectric element with a multi-layer structure according to an embodiment of the present disclosure.

FIG. 4 is a schematic diagram of an imaging module according to an embodiment of the present disclosure.

FIG. 5 is a structural schematic diagram of a limiting layer for forming a limiting groove according to an embodiment of the present disclosure.

FIG. 6 is a top view of FIG. 1B along a cutting line X-X.

FIG. 7 is a structural schematic diagram of a limiting groove according to an embodiment of the present disclosure.

FIG. 8A is a structural schematic diagram of an elastic limiting piece according to an embodiment of the present disclosure.

FIG. 8B is a structural schematic diagram of an elastic limiting piece according to an embodiment of the present disclosure.

FIG. 9 is a schematic diagram of an imaging module according to an embodiment of the present disclosure.

FIG. 10 is a schematic diagram of an imaging module according to an embodiment of the present disclosure.

FIG. 11 is a schematic diagram of an imaging module according to an embodiment of the present disclosure.

FIG. 12 to FIG. 14 are positional relationship diagrams of a piezoelectric element and a moved element according to different embodiments of the present disclosure.

FIG. 15 is a schematic diagram of an imaging module according to an embodiment of the present disclosure.

FIG. 16 is a schematic diagram of an imaging module according to an embodiment of the present disclosure.

FIG. 17 is a schematic diagram of an imaging module according to an embodiment of the present disclosure.

FIG. 18 is a schematic diagram of a piezoelectric element with a rotating shaft structure according to an embodiment of the present disclosure.

FIG. 19 is a schematic diagram of an imaging module with the piezoelectric element shown in FIG. 18.

FIG. 20 is a schematic diagram of an imaging module according to an embodiment of the present disclosure.

FIG. 21 is a schematic diagram of an imaging module according to an embodiment of the present disclosure.

FIG. 22A is a schematic diagram of electrical connection of a moved element and an external signal through a wiring layer of a piezoelectric element according to an embodiment of the present disclosure.

FIG. 22B is a schematic diagram of electrical connection of a moved element and an external signal through a wiring layer of a piezoelectric element according to an embodiment of the present disclosure.

FIG. 23 is a schematic diagram of an imaging module according to an embodiment of the present disclosure.

### DESCRIPTION OF REFERENCE NUMERALS

10—Circuit board; 20—piezoelectric element; 201—rotating shaft; 21—first electrode; 211—odd-layer electrode; 22—second electrode; 221—even-layer electrode; 23—piezoelectric film; 24—supporting layer; 25—insulating layer; 251—first electrode leading-out end; 252—second electrode leading-out end; 26—conductive structure; 27—elastic limiting piece; 27A—elastic limiting piece; 27A—elastic limiting piece; 27B—elastic limiting piece; 30—moved element; 40—limiting groove; 41—first film layer; 42—second film layer; 43—third film layer; 50—supporting block; 51—first-layer supporting block; 52—second-layer supporting block; 61—third electrical connection end; 62—fourth electrical connection end; 63—conductive plug; 71—first electrical connection end; 72—second electrical connection end; 73—flexible connection piece; 74—fifth electrical connection end; 75—wiring layer; 76—lead; 77—sixth electrical connection end.

### DESCRIPTION OF THE EMBODIMENTS

A method for manufacturing an element bulk acoustic resonator of the present disclosure is further described below in detail with reference to the accompanying drawings and the specific embodiments. According to the following description and the accompanying drawings, the advantages and features of the present disclosure will be clearer. However, it should be noted that the concept of the technical solution of the present disclosure may be implemented according to various different forms, and is not limited to the specific embodiments described herein. The accompanying drawings all adopt very simplified forms and use inaccurate scale, which are only used for conveniently and clearly assisting in describing the objective of the embodiment of the present disclosure.

It should be understood that when an element or layer is referred to as “on”, “adjacent to”, “connected to” or “coupled to” other elements or layers, the element or layer may be directly on, adjacent to, connected to or coupled to other elements or layers, or there may be an element or layer between the element or layer and other elements or layers. On the contrary, when an element is referred to as “directly on”, “directly adjacent to”, “directly connected to” or “directly coupled to” other elements or layers, there is no element or layer between the element or layer and other elements or layers. It should be understood that although terms first, second, third, etc. may be used to describe various elements, parts, regions, layers and/or portions, these elements, parts, regions, layers and/or portions should not be limited by these terms. These terms are only used to distinguish one element, part, region, layer or portion from another element, part, region, layer or portion. Therefore, without departing from the instruction of the present disclosure, a first element, part, region, layer or portion discussed below may be represented as a second element, part, region, layer or portion.

Spatial relationship terms such as “under”, “below”, “over”, “above”, etc. may be used herein for the convenience of description so as to describe a relationship between one element ore feature shown in the drawings and other elements or features. It should be understood that in addition to an orientation shown in the drawings, the spatial relationship terms are intended to further include different orientations of devices during use and operation. For example, if devices in the drawings are turned over, an element or feature which is described to be “below” or “under” other elements or features will be oriented to be “above” other elements or features. Therefore, exemplary terms “under” and “below” may include upper and lower orientations. Devices may be otherwise oriented (rotating by 90 degrees or adopting other orientations), and spatial description words used therein are accordingly explained.

The terms used herein are only intended to describe the specific embodiments and not to limit the present disclosure. When used herein, the singular forms “a”, “an” and “the” are also intended to include the plural forms, unless the context clearly indicates otherwise. It should also be understood that terms “comprise” and/or “include”, when used in the specification, are used to determine the presence of the feature, integer, step, operation, element and/or part, but do not exclude the presence or addition of more other features, integers, steps, operations, elements, parts and/or groups. When used herein, the term “and/or” includes any and all combinations of related listed items.

If the method of the present disclosure includes a series of steps, the order of these steps presented herein is not necessarily the only order in which these steps may be performed, and some steps may be omitted and/or some other steps not described herein may be added to the method. If elements in a certain drawing are as same as elements in other drawings, these elements may be easily identified, but in order to make the description of the drawings clearer, the description will not mark the reference numerals of all the same elements in each drawing.

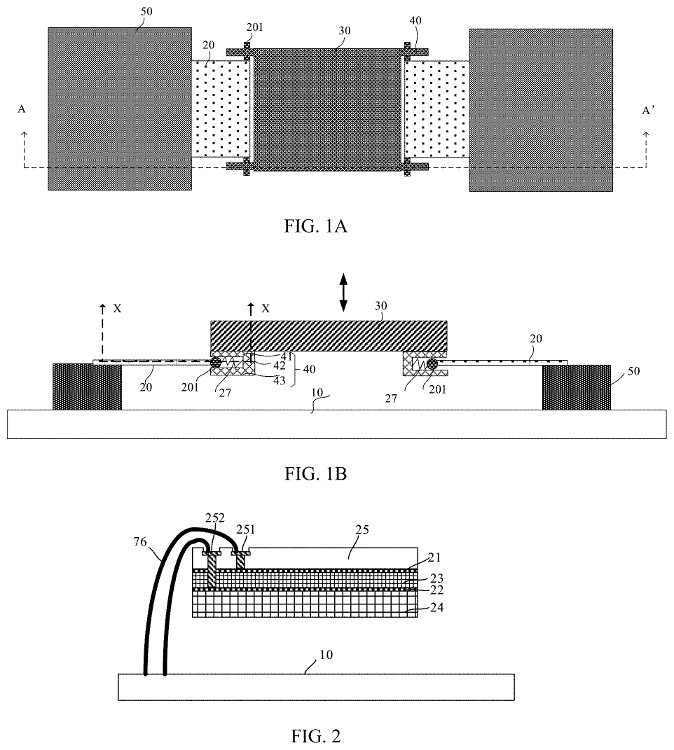

An embodiment of the present disclosure provides an imaging module. FIG. 1A is a schematic diagram of an imaging module according to an embodiment of the present disclosure, and FIG. 1B is a sectional view of FIG. 1A along a cutting line A-A′. Referring to FIG. 1A and FIG. 1B, the imaging module includes: a moved element 30, including a lens group, an imaging sensing element, an aperture, a reflector or a lens; a limiting groove 40, formed in a surface of the moved element 30; a piezoelectric element 20, including a movable end and a fixed end, wherein the movable end is provided with a rotating shaft 201, the rotating shaft 201 is arranged in the limiting groove 40, the limiting groove 40 provides a moving space for the rotating shaft 201, and the movable end drives the moved element 30 to move upwards or downwards when the piezoelectric element 20 is in a power-on state; an elastic limiting piece 27, one end of which is connected to the movable end of the piezoelectric element 20 and the other end is located in the limiting groove 40, wherein the elastic limiting piece 27 is in a free state when the piezoelectric element 20 is in a free state, and the elastic limiting piece 27 is compressed or stretched when the movable end of the piezoelectric element 20 is warped; a supporting block, configured to support and fix the piezoelectric element 20, wherein the fixed end of the piezoelectric element 20 is fixed at the supporting block 50; and an external signal connection end, electrically connected to an electrode in the piezoelectric element 20.

Specifically, referring to FIG. 2, the piezoelectric element 20 includes a supporting layer 24 and a piezoelectric laminated structure located on the supporting layer 24. The piezoelectric laminated structure includes a second electrode 22, a piezoelectric film 23 and a first electrode 21 which are stacked sequentially from bottom to top, wherein an insulating layer 25 is arranged above the first electrode 21, the first electrode 21 and the second electrode 22 are connected to a first electrode leading-out end 251 and a second electrode leading-out end 252 respectively, and the first electrode leading-out end 251 and the second electrode leading-out end 252 are both located in the insulating layer 25. In the present disclosure, the first electrode leading-out end 251 and the second electrode leading-out end 252 may be both located on a bottom surface of the piezoelectric 20, that is, the first electrode leading-out end 251 and the second electrode leading-out end 252 are located in the supporting layer 24, or the first electrode leading-out end 251 and the second electrode leading-out end 252 may also be located on a top surface and the bottom surface of the piezoelectric element 20 respectively, which is not limited by the present disclosure.

Continuously referring to FIG. 1B and FIG. 2, the first electrode leading-out end 251 and the second electrode leading-out end 252 are located on the top surface of the piezoelectric element 20, and the piezoelectric element 20 is located on the top surface of the supporting block 50. The first electrode leading-out end 251 and the second electrode leading-out end 252 directly serve as external signal connection ends and are electrically connected to a circuit board 10 respectively through one lead 76, such that the circuit board 10 may apply a voltage to the piezoelectric element 20, and a voltage difference is generated between an upper surface and a lower surface of a piezoelectric film 23, thereby shrinking the piezoelectric film 23. However, since the supporting layer 24 cannot extend and retract, the piezoelectric element 20 is warped upwards or downwards (the warping direction and the warping degree depend on the voltage applied to the upper and lower surfaces of the piezoelectric film 23) after being powered on, such that the piezoelectric element 20 is entirely bent upwards or downwards and the moved element 30 may entirely move upwards or downwards, thereby changing a vertical position of the moved element 30 and realizing optical automatic focusing. After automatic focusing is completed, when necessary, the voltage applied to the piezoelectric element 20 on one side on of the moved element 30 may be changed, such that the moved element 30 inclines, thereby changing the angle of the moved element 30, correcting an optical warping angle of the moved element 30 and preventing optical jittering. It should be understood that the present disclosure is not limited to connecting the piezoelectric element 20 and the circuit board 10 directly through the lead 76, an electrical connection end may be arranged on the top surface of the supporting block 50, two electrode leading-out ends of the piezoelectric element 20 are electrically connected to the electrical connection end respectively through the lead, and then the electrical connection end on the top surface of the supporting block 50 is electrically connected to the circuit board 10 through another interconnection structure (such as a lead or conductive plug), so that a length of the lead 76 may be shortened.

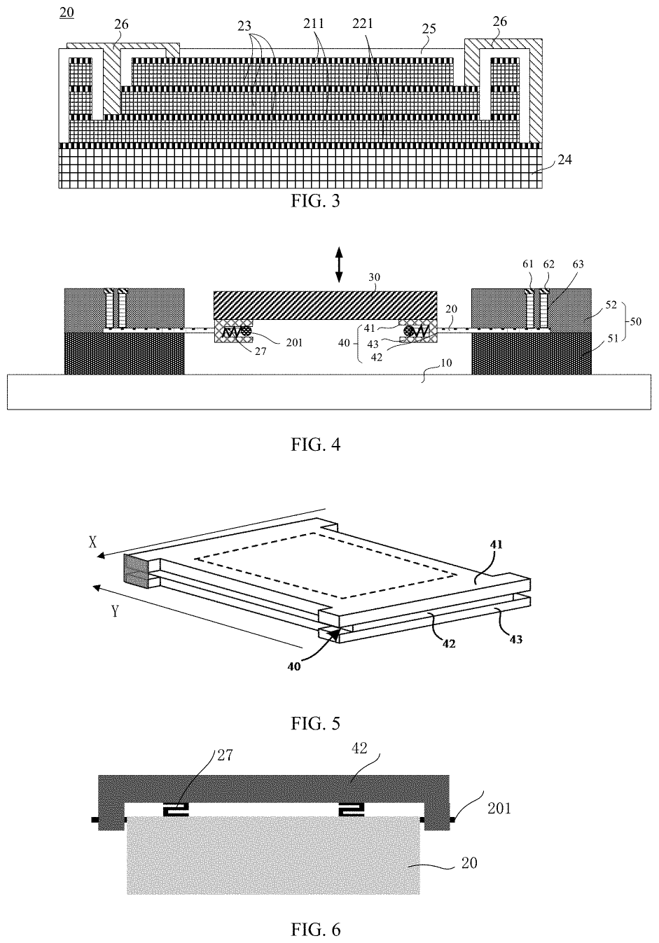

The piezoelectric film 23 needs to be made of a piezoelectric material which may be deformed when being electrified, for example, a quartz crystal, aluminium nitride, zinc oxide, lead zirconate titanate, barium titanate, lithium gallate, lithium germanate or titanium germanate, etc. A material of the supporting layer 24 is a non-conductive dielectric material such as silicon oxide, silicon nitride and the like. In addition, the piezoelectric laminated structure of the piezoelectric element 20 may not be limited to only one layer of piezoelectric film 23. Referring to FIG. 3, the piezoelectric laminated structure of the piezoelectric element 20 may be a piezoelectric laminated structure with three layers of piezoelectric films 23, electrodes are distributed on an upper surface and an lower surface of each layer of piezoelectric film 23, and the adjacent two layers of piezoelectric films 23 share the electrode located therebetween, so there are totally four layers of electrodes on the three layers of piezoelectric films 23, the electrodes are counted sequentially from bottom to top, the odd-layer electrodes 211 are electrically connected together through a conductive structure 26, the even-layer electrodes 221 are electrically connected together through another conductive structure 26, a part, extending into the piezoelectric laminated structure, of the conductive structure 26 needs to be located in the insulating layer 25, and only the end part of the conductive structure 26 is in contact with the electrodes requiring electrical connection. Tops of the two conductive structures 26 may serve as the first electrode leading-out end 251 and the second electrode leading-out end 252 respectively, such that the first electrode leading-out end 251 and the second electrode leading-out end 252 are both located on a top surface of the piezoelectric element 20. In other embodiments, the piezoelectric laminated structure is not limited to including three layers of piezoelectric films and may also include three layers, four layers, five layers or six layers, etc. The warping ability of the piezoelectric element 20 may be improved by increasing the number of the piezoelectric films 23, such that the piezoelectric element 20 can move the moved element 30 with larger mass. Further, the electrical connection mode of the odd-layer electrodes 211 and the even-layer electrodes 221 are not limited to the conductive structure 26 shown in FIG. 3, and the electrical connection mode of the odd-layer electrodes 211 and the even-layer electrodes 221 may also be electrically connected through a conductive plug and an interconnecting line. The two conductive structures 26 may lead the odd-layer electrodes 211 and the even-layer electrodes 221 to the bottom surface of the supporting layer 24, such that the first electrode leading-out end 251 and the second electrode leading-out end 252 are both located on the bottom surface of the piezoelectric element 20, or the two conductive structures 26 may also lead the odd-layer electrodes 211 and the even-layer electrodes 221 to the top surface of the piezoelectric element 20 and the bottom surface of the supporting layer 24 respectively, such that the first electrode leading-out end 251 and the second electrode leading-out end 252 are both located on the top surface and the bottom surface of the piezoelectric element 20, which are thus not illustrated one by one. It should be understood that in order to ensure the same warping direction of the three layers of piezoelectric films, the polarities of the adjacent two layers of piezoelectric films are opposite.

Continuously referring to FIG. 1B, a first film layer 41, a second film layer 42 and a third film layer 43 are arranged on a lower surface of the moved element 30, and the limiting groove 40 is surrounded by three film layers. The limiting groove 40 is not limited to being located on the lower surface of the moved element 30, and may also be located on the upper surface of the moved element 30 or be located on a side surface of the moved element 30. In the present disclosure, the limiting groove 40 is not limited to being surrounded by additionally set film layer, and the limiting groove 40 may be formed by the moved element 30 itself. For example, the side surface of the moved element 30 is recessed for the limiting groove 40, or when the limiting groove is located on the lower surface, the lower surface of the moved element may serve as an upper film layer of the limiting groove 40, and when the limiting groove 40 is located on the upper surface, the upper surface of the moved element 30 serves as a lower film layer of the limiting groove.

A rotating shaft 201 is arranged on an end part of the piezoelectric element 20, the rotating shaft 201 is arranged in the limiting groove 40, the limiting groove 40 provides a moving space for the rotating shaft 201, and the rotating shaft 201 drives the moved element 30 to move upwards or downwards when the piezoelectric element 20 is in a power-on state. The limiting groove 40 providing a moving space for the rotating shaft 201 means that a size of the limiting groove 40 is greater than a size of the movable end of the rotating shaft 201, that is, a length of the limiting groove 40 is greater than a length of the rotating shaft 201, and a height of the limiting groove 40 is greater than or equal to a diameter of the rotating shaft 201, so that the rotating shaft 201 can freely rotate and slide in the limiting groove 40. When the piezoelectric element 20 is warped, the rotating shaft 201 can rotate in the limiting groove 40 so as to prevent the movable end of the piezoelectric element 20 from being stuck. When the height of the limiting groove 40 is equal to the diameter of the rotating shaft 201, the lifting and lowering amount of the moved element 30 may be controlled well, and it is unnecessary to overcome a space allowance between the rotating shaft 201 and the limiting groove 40.

Continuously referring to FIG. 1B, an elastic limiting piece 27 is arranged in the limiting groove 40. Specifically, an opening direction of the limiting groove 40 faces towards the direction of the fixed end of the piezoelectric element. When the movable end of the piezoelectric element 20 is warped upwards or downwards, the piezoelectric element 20 is shortened in a horizontal direction, and the rotating shaft 201 moves towards the opening direction of the limiting groove 40. Due to the presence of a friction force, the moved element 30 moves towards the moving direction of the rotating shaft 201 while moving upwards or downwards; however, the ideal state is that the moved element 30 only moves up and down in a vertical direction. In this example, one end of the elastic limiting piece 27 is connected to the rotating shaft 201 and the other end of the elastic limiting piece is connected to a side wall 42 of the limiting groove 40. The function of the elastic limiting piece 27 is similar to that of a spring. When the piezoelectric element 20 is in the free state, the elastic limiting piece 27 is in the free state. When the piezoelectric element 20 is warped, the rotating shaft 201 moves towards the opening direction of the limiting groove 40 and the elastic limiting piece 27 is stretched, and at this time, the elastic limiting piece 27 applies a pull-back force towards an opposite direction (a direction towards the side wall 42) to the rotating shaft 201 and the rotating shaft 201 is limited from moving towards the opening direction of the limiting groove 40, thereby limiting the horizontal movement of the moved component 30.

In this example, one end of the elastic limiting piece 27 is connected to the rotating shaft 201 and the other end of the elastic limiting piece is connected to a side wall 42 of the limiting groove 40. In other examples, the elastic limiting piece 27 is connected to one end of the side wall 42 of the limiting groove 40, and may also be connected to a top wall 41 or a bottom wall 43 of the limiting groove 40, as long as the elastic limiting piece 27 is fixed in the limiting groove 40. The elastic limiting piece 27 is connected to one end of the rotating shaft 201, may also be connected to the edge of the movable end of the piezoelectric element 20, and may be located at a position closer to the limiting groove 40.

Referring to FIG. 4, the opening direction of the limiting groove 40 departs from the direction of the fixed end of the piezoelectric element 20. When the movable end of the piezoelectric element 20 is warped upwards or downwards, the piezoelectric element 20 is shortened in the horizontal direction and the rotating shaft 201 moves towards the direction of the side wall 42 of the limiting groove 40. Due to the presence of a friction force, the moved element 30 moves towards the moving direction of the rotating shaft 201 while moving upwards or downwards. In this example, one end of the elastic limiting piece 27 is connected to the rotating shaft 201 and the other end of the elastic limiting piece is placed in the limiting groove 40. When the piezoelectric element 20 is in the free state, the elastic limiting piece 27 is also in the free state. When the piezoelectric element 20 is warped, the rotating shaft 201 moves towards the direction of the side wall 42 of the limiting groove 40, the elastic limiting piece 27 is compressed due to the blockage of the side wall 42, the elastic limiting piece 27 applies a resilience force towards an opposite direction (towards the opening direction of the limiting groove 40) to the rotating shaft 201, and the rotating shaft 201 is limited from moving towards the direction of the side wall 42 of the limiting groove 40, thereby limiting the horizontal movement of the moved element 30.

In this example, when the piezoelectric element 20 is warped, the elastic limiting piece 27 moves towards the direction of the side wall 42 of the limiting groove 40 and is blocked by the side wall 42 to be compressed, and the side wall 42 plays a role in blocking the movement of the elastic limiting piece 27; therefore, the elastic limiting piece 27 may not be connected and fixed with the limiting groove 40. When the limiting groove 40 is not provided with the side wall 42 for blocking the movement of the elastic limiting piece 27, it is still necessary to fix the elastic limiting piece 27 in the limiting groove 40. Assuming that there is a certain distance between the elastic limiting piece 27 and the side wall 42, when the elastic limiting piece 27 is compressed by pressure, the elastic limiting piece 27 firstly moves towards the direction of the side wall 42 and then is compressed when being in contact with the side wall 42, and the elastic limiting piece 27 does not limit the horizontal movement of the moved element 30 before being compressed. In order to limit the movement of the rotating shaft 201 better, the smaller the distance between the elastic limiting piece 27 and the side wall 42, the better. In this example, when the elastic limiting piece 27 is in the free state, the elastic limiting piece is in contact with the side wall 42.

Referring to FIG. 5, the limiting groove 40 is surrounded by three film layers. When the moved element 30 does not need to transmit light, the three film layers may be distributed on the whole surface (upper surface or lower surface) of the moved element; and when the moved element needs to transmit light, the three film layers may only be distributed on the edge of the moved element, that is, there is no film layer in an area in a dotted line in FIG. 5. The three film layers are the first film layer 41, the second film layer 42 and the third film layer 43 respectively, and the first film layer 41, the second film layer 42 and the third film layer 43 are sequentially deposited on the surface of the moved element 30. Two sides of the first film layer 41 and the third film layer 43 stretch out relative to the second film layer 42 to form a stretch-out portion, and the limiting groove 40 is surrounded by the stretch-out portion and an end part of the second film layer 42. A length of the film layer is greater than a length of the moved element 30, thereby preventing from being stuck when the piezoelectric element 20 is warped.

Referring to FIG. 6, FIG. 6 is a top view of FIG. 1B along a cutting line X-X. It is a schematic diagram of a connection position of the elastic limiting piece. When three film layers shown in FIG. 5 are arranged on the surface of the moved element 30, one end of the elastic limiting piece 27 is connected to the end part of the movable end of the piezoelectric element 20 and the other end of the elastic limiting piece 27 is connected to an end face of the second film layer 42, and at this time, the elastic limiting piece 27 is located outside the limiting groove 40; therefore, it is not limited to the size of the limiting groove 40, the size and the number of the elastic limiting piece 27 may increase, of course, when the elastic limiting piece 27 is in the limiting groove 40, a plurality of the elastic limiting pieces may be provided according to the size of the limiting groove 40. This setting mode enhances the strength of the elastic limiting piece 27 and the ability of limiting the horizontal movement of the moved element 30.

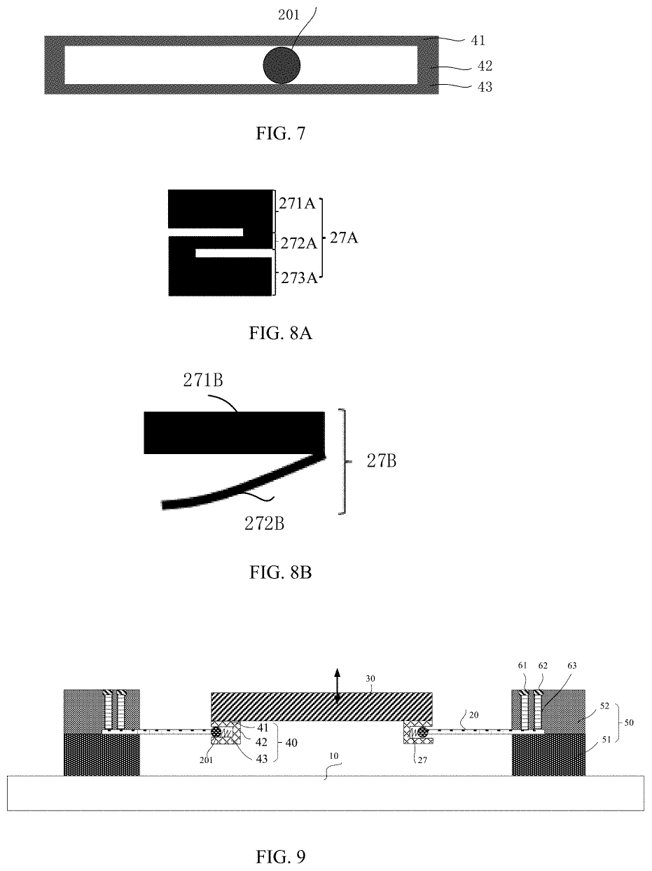

Continuously referring to FIG. 5, the limiting groove 40 is provided with an opening along a telescopic direction of the piezoelectric element 20. The piezoelectric element 20 is warped, the rotating shaft 201 moves towards the opening direction of the limiting groove 40, and there is a risk of falling out of the limiting groove 40. Referring to FIG. 7, it is a structural schematic diagram of a limiting groove. In conjunction with FIG. 5, the limiting groove 40 is provided with an opening along a length direction (an arrowhead X direction) of the piezoelectric element and there is a risk of falling down from the opening when the rotating shaft moves to the opening. FIG. 7 is a structural schematic diagram of a cross section of the limiting groove viewed along a width direction (an arrowhead Y direction) of the piezoelectric element after the opening is closed. The cross section of the limiting groove 40 is annular. When sliding to the edge of the limiting groove 40, the rotating shaft 201 does not fall from the limiting groove 40 due to blockage.

There is no strict requirement on the structure of the elastic limiting piece 27, as long as the elastic limiting piece 27 is elastic and telescopic and may limit the movement of the rotating shaft 201. FIG. 8A and FIG. 8B show structures of two elastic limiting pieces 27. Referring to FIG. 8A, the elastic limiting piece 27A includes: a first portion 271A, a second portion 273A, and a middle portion 272A located between the first portion 271A and the second portion 273A, wherein the middle portion 272A is of a horizontal strip-shaped structure, and the first portion 271A and the second portion 273A are provided with a vertical beam and are connected with the middle portion 272A through the vertical beam. A width and a thickness of the middle portion 272A meet set values, such that the middle portion 272A has flexibility, and the first portion 271A and the second portion 272A are configured to be connected with the limiting groove 40 and the rotating shaft 201. When the elastic limiting piece 271A is subjected to a pull force or pressure, the middle portion 272A may be deformed. It should be understood that the set values of the width and the thickness of the middle portion 272A are relevant to a material of the middle portion 272A. When the middle portion 272A is made of different materials, the set values will change correspondingly, as long as the set values can ensure that the middle portion 272A has flexibility. In the present disclosure, the middle portion 272A is not limited to a strip-shaped structure, and may also be arc-shaped, wave-like, etc.; and the first portion 271A and the second portion 273A are not limited to being connected with the middle portion 273A through the vertical beam, which is not limited by the present disclosure. Further, the first portion 271A and the second portion 273A may have flexibility, and may also not have flexibility.

Referring to FIG. 8B, the elastic limiting piece 27B includes: a first portion 271B and a second portion 272B, wherein the second portion 272B has elasticity, and the first portion 271B may have or not have elasticity. When the elastic limiting piece 27B is subjected to a pressure, the second portion 272B moves towards a direction close to the first portion 271B, and the second portion 272B has a resilience force towards a direction away from the first portion 271B; and when the elastic limiting piece 27B is subjected to a pull force, the second portion 272B moves towards the direction away from the first portion 271B, and the second portion 272B has a pull-back force towards the direction close to the first portion 271B. The elastic limiting piece 27 may be an independent structure, and may also be an integrated structure with the rotating shaft 210 or the piezoelectric element 20. When the elastic limiting piece 27 is the independent structure, the elastic limiting piece 27 adheres to a corresponding position (for example, in the limiting groove 40, on the rotating shaft 210 and at the edge of the movable end of the piezoelectric element 20) through a dry film or viscose. When the elastic limiting piece 27 is the integrated structure with the rotating shaft 210 or the piezoelectric element 20, the elastic limiting piece 27 is manufactured at the same time when the rotating shaft 210 or the piezoelectric element 20 is manufactured. It should be noted that the elastic limiting piece 27 and the piezoelectric element 20 are insulated, and the rotating shaft 210 and the piezoelectric element 20 are also insulated. A method for forming insulation may be implemented by the following two modes: materials for forming the elastic limiting piece 27 and the rotating shaft 210 are insulating materials, or an electrical isolation structure (such as an insulating layer or an air gap) is arranged between the elastic limiting piece 27 and the piezoelectric element 20.

Continuously referring to FIG. 1B, the fixed end of the piezoelectric element 20 is located on the supporting block 50, and the movable end stretches out of the supporting block 50 to form a cantilever structure. In other examples, the piezoelectric element 20 may be integrally located on the supporting block 50. When the piezoelectric element 20 is integrally located on the supporting block 50, it is suitable for occasions where the moved element 30 needs to be lifted. When the movable end of the piezoelectric element 20 stretches out of the supporting block 50, it may be applied to occasions where the moved element 30 needs to be lifted upwards or move downwards. The supporting block 50 is connected with the fixed end of the piezoelectric element 20 through viscose or a dry film.

Further, a material of the supporting block 50 is a dielectric material and may be annular and arranged around the moved element 30, and may support the piezoelectric element 20 well; or the supporting block 50 includes a plurality of sub-supporting blocks distributed along a circumferential direction, and the plurality of sub-supporting blocks are spaced or in contact with each other so as to save materials and reduce weight. When the plurality of piezoelectric elements 20 are not at the same height, the heights of the supporting blocks 50 may be inconsistent. In the present disclosure, the supporting block 50 may not be annular, for example, the supporting block 50 is only located on two sides or four sides of the moved element 30.

Referring to FIG. 9, an external signal connection end of the piezoelectric element 20 includes a third electrical connection end 61 and a fourth electrical connection end 62, and the first electrode leading-out end 251 and the second electrode leading-out end 252 are both located on a top surface of the piezoelectric element 20. The supporting block 50 includes a first layer of supporting block 51 and a second layer of supporting block 52, and the fixed end of the piezoelectric element 20 is located between the first layer of supporting block 51 and the second layer of supporting block 52. The third electrical connection end 61 and the fourth electrical connection end 62 are located on the top surface of the supporting block 50 and over the piezoelectric element 20. The third electrical connection end 61 is electrically connected with the first electrode leading-out end 251B of the piezoelectric element 20 through the conductive plug 63, the fourth electrical connection end 62 is electrically connected with the second electrode leading-out end 252 of the piezoelectric element 20 through the conductive plug 63, and the two conductive plugs 63 are located in the second layer of supporting block 52.

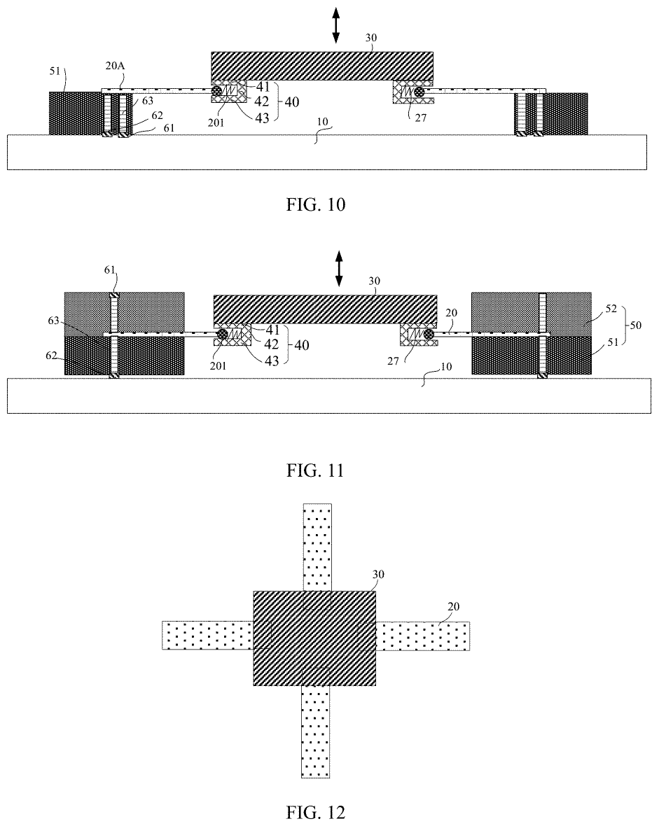

Referring to FIG. 10, the supporting block is a first layer of supporting block 51, and the first electrode leading-out end 251 and the second electrode leading-out end 252 of the piezoelectric element 20 are both located on the bottom surface of the piezoelectric element 20. The third electrical connection end 61 and the fourth electrical connection end 62 are located on the bottom surface of the first layer of supporting block 51 and under the piezoelectric element 20. The third electrical connection end 61 is electrically connected with the first electrode leading-out end 251 of the piezoelectric element 20 through the conductive plug 63, the fourth electrical connection end 62 is electrically connected with the second electrode leading-out end 252 of the piezoelectric element 20 through the conductive plug 63, and the two conductive plugs 63 are located in the first layer of supporting block 51.

Referring to FIG. 11, when the first electrode leading-out end 251 and the second electrode leading-out end 252 of the piezoelectric element 20 are located on the top surface and the bottom surface of the piezoelectric element 20 respectively, the third electrical connection end 61 and the fourth electrical connection end 62 are located on the top surface and the bottom surface of the supporting block 50 and are located over and under the piezoelectric element 20, the third electrical connection end 61 is electrically connected with the first electrode leading-out end 251 of the piezoelectric element 20 through the conductive plug 63, the fourth electrical connection end 62 is electrically connected with the second electrode leading-out end 252A of the piezoelectric element 20 through the conductive plug 63, and the two conductive plugs 63 are located in the first layer of supporting block 51 and the second layer of supporting block 52 respectively.

It should be understood that when the third electrical connection end 61 and the fourth electrical connection end 62 are not over against the piezoelectric element 20, the third electrical connection end 61 and the fourth electrical connection end 62 may be electrically connected with the first electrode leading-out end 251 and the second electrode leading-out end 252 through rewiring.

Continuously referring to FIG. 1B, there are a pair of piezoelectric elements 20 which are symmetrically distributed on two sides of the moved element 30, a connecting line between the pair of piezoelectric elements 20 serves as a rotating shaft, and the moved element 30 may rotate along one rotating shaft so as to change an angle of inclination in a direction.

Referring to FIG. 12, there are two pairs of piezoelectric elements 20 which are distributed on four sides of the moved element 30, a connecting line between each pair of piezoelectric elements 20 serves as a rotating shaft, there are two rotating shafts in total, and the moved element 30 may rotate along the two rotating shafts so as to change angles of inclination in two directions.

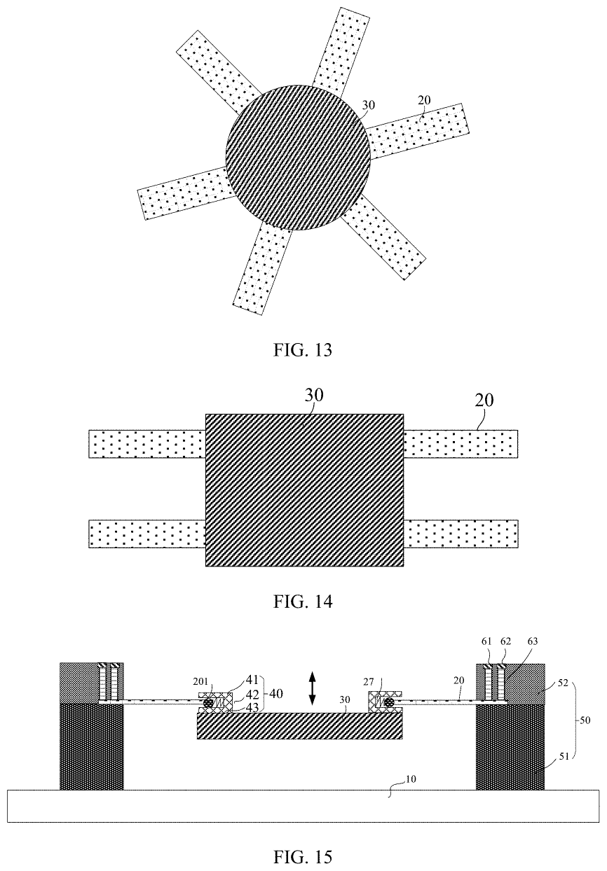

Referring to FIG. 13, there are three pairs of piezoelectric elements 20 which are distributed evenly along a circumferential direction, a connecting line between each pair of piezoelectric elements 20 serves as a rotating shaft, there are three rotating shafts in total, and the moved element 30 may rotate along the three rotating shafts so as to change angles of inclination in three directions.

Referring to FIG. 14, the opposite two sides of the moved element 30 are connected with two piezoelectric elements 20, such that the two piezoelectric elements 20 are warped upwards or downwards synchronously (the warping amplitudes are the same). In this way, the two piezoelectric elements 20 together support one side of the moved element 30 and may be suitable for the occasion where the size of the piezoelectric element 20 is small and the size of the moved element 30 is large, or may be suitable for the occasion where the mass of the moved element 30 is large. In the present disclosure, the opposite two sides of the moved element 30 are not limited to being connected with two piezoelectric elements 20, and may be connected with three, four and five piezoelectric elements.

Of course, there may be four pairs, five pairs or six pairs of piezoelectric elements 20. Each pair of piezoelectric elements 20 are not limited to being arranged symmetrically along the center of the moved element 30 and may be arranged asymmetrically. If there are more pairs of piezoelectric elements 20 and the rotating shafts of the moved element 30 may be increased, multi-dimensional rotation is realized. The moved element 30 is not limited to square or round and may be of other shapes, which is not limited by the present disclosure. It may be understood that the piezoelectric elements 20 appear in pairs to control the movement of the moved element 30. In fact, the piezoelectric element 20 may not appear in pairs, for example, three piezoelectric elements 20 are distributed evenly along the circumferential direction of the moved element 30, which is not illustrated by this embodiment one by one.

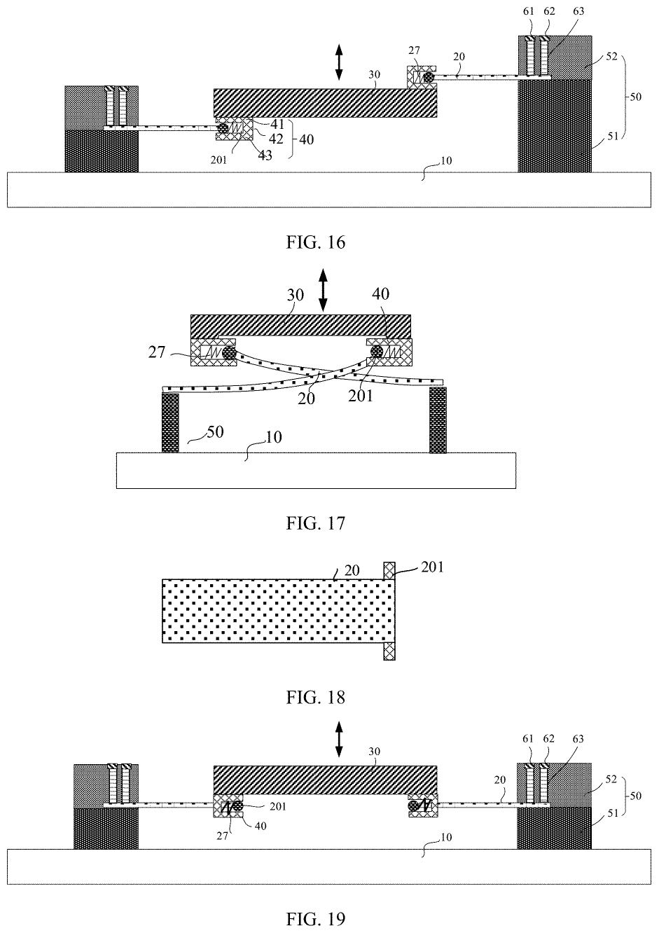

In the present disclosure, one piezoelectric element 20 corresponds to one pair of limiting grooves 40. Two pairs of limiting grooves 40 are not limited to being fixed on a lower surface of the moved element 30. As shown in FIG. 15, the two pairs of limiting grooves 40 are all fixed on an upper surface of the moved element 30. As shown in FIG. 16, one pair of the two pairs of limiting grooves 40 are fixed on the upper surface of the moved element 30 and the other pair are fixed on the lower surface of the moved element 30. At this time, the supporting blocks 50 which support two piezoelectric elements 20 have different heights, that is, in order to support the piezoelectric element 20, the height of the supporting block 50 may be adjusted according to the position of the piezoelectric element 20.

Referring to FIG. 16, the two paired piezoelectric elements 20 are mutually distributed on two sides of the center of the moved element 30. However, it should be understood that, as shown in FIG. 17, the two paired piezoelectric elements 20 may be arranged below the moved element in an overlapping manner. That is, the movable end of the piezoelectric element 20 is selected in the limiting groove 40 on one side far away from the moved element 30 (each piezoelectric element 30 is configured to move the opposite side of the moved element 30). At this time, the length of the piezoelectric element 20 may be increased. When the mass of the moved element 30 is large, the piezoelectric element can be lifted easily. In this example, the fixed end of the piezoelectric element 20 is located on an outer side of the moved element 30. In other examples, the fixed end of the piezoelectric element 20 may also be located below the moved element 30.

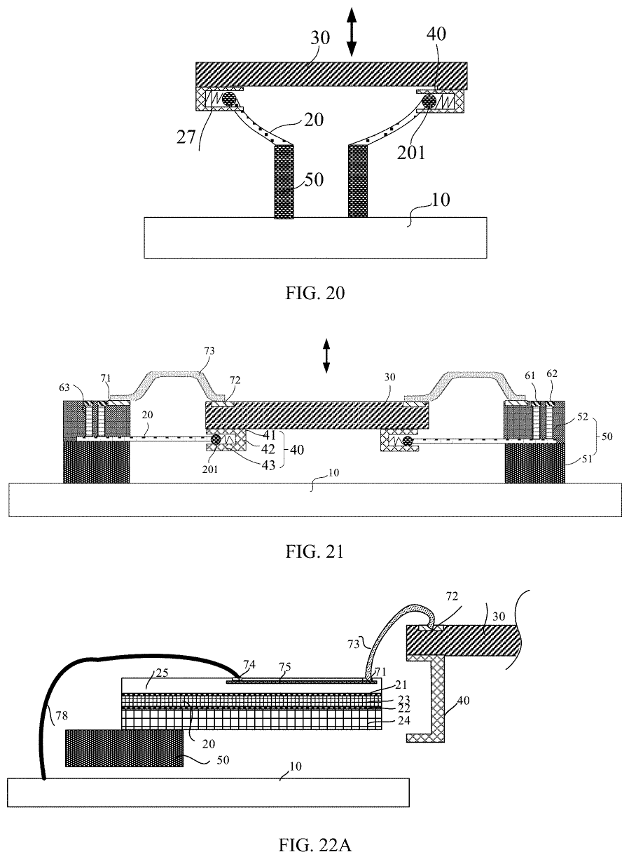

Referring to FIG. 18 and FIG. 19, in the present disclosure, two paired piezoelectric elements 20 are mutually distributed on two sides of the center of the moved element 30, an opening of the limiting groove 40 along a telescopic direction of the piezoelectric element 20 may be back on to the supporting block 50, and at his time, the rotating shaft 201 is located on two sides of the movable end of the piezoelectric element 20, and an opening of the rotating shaft 201 stretches into the limiting groove 40 from the limiting groove 40 along a length direction of the rotating shaft. Further, as shown in FIG. 19, the fixed position of the supporting block 50 and the piezoelectric element 20 is located on the outer side of the moved element 30. As shown in FIG. 20, the fixed position of the supporting block 50 and the piezoelectric element 20 may also be located at a lower space of the moved element 30. In this embodiment, the supporting block 50, and the fixed position of the supporting block 50 and the piezoelectric element 20 are located under the moved element 30, so that the fixed end of the piezoelectric element 20 is closer to the center of the moved element 30 than the movable end. Of course, the supporting block 50 is not limited to being completely located under the moved element 30, and may be partially located under the moved element 30. In this way, the supporting block 50 may completely or partially covered with the moved element 30, thereby saving the occupied area of the supporting block 50, reducing the area of the whole imaging module and being beneficial to shortening the size.

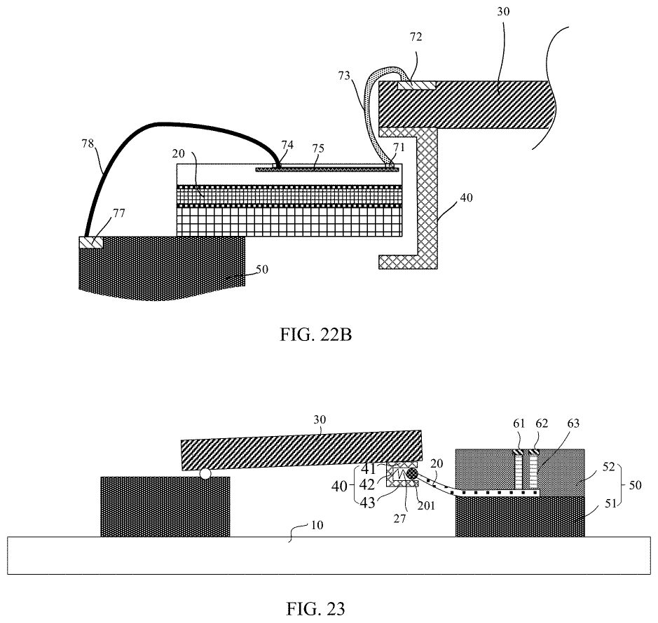

Referring to FIG. 21, when the moved element 30 needs to be connected with an external electrical signal, for example, the moved element 30 is an imaging sensing element, a top surface of the supporting block 50 is provided with a first electrical connection end 71, and an edge of the imaging sensing element is provided with a second electrical connection end 72. The closer the first electrical connection end 71 is to the imaging sensing element, the better. The first electrical connection end 71 and the second electrical connection end 72 are electrically connected through a flexible connection piece 73, and the first electrical connection end 71 may be electrically connected with the circuit board 10 through a lead (the lead is not shown in the figure), so that the circuit board 10 provides power or signals to the imaging sensing element. Further, when the fixed end of the piezoelectric element 20 is located on the top surface of the supporting block 50, referring to FIG. 22A, the first electrical connection end 71 is located on the top surface of the piezoelectric element 20. Specifically, a wiring layer 75 is arranged on the top surface of the piezoelectric element 20 and is located in the insulating layer 25, and two ends of the wiring layer are respectively provided with a first electrical connection end 71 and a fifth electrical connection end 74 which are exposed out of the insulating layer 25. The first electrical connection end 71 is closer to the moved element 30 than the fifth electrical connection end 74, the first electrical connection end 71 is electrically connected with the second electrical connection end 72 through a flexible connection piece 73, and the fifth electrical connection end 74 is electrically connected with the circuit board 10 through a lead 78, so that the circuit board 10 provides power or signals for the imaging sensing element. Compared with the method for electrically connecting the second electrical connection end 72 of the imaging sensing element with the circuit board 10 directly through the lead, the length of the flexible connection piece 73 in this embodiment may be short (the closer the first electrical connection end 71 is to the imaging sensing element, the shorter the flexible connection piece 73 is); moreover, when the moved element 30 moves upwards or downwards, the flexible connection piece 73 is not pulled.

In the present disclosure, the first electrical connection end 71 is not limited to be electrically connected with the circuit board 10 through the lead, as shown in FIG. 22B, a sixth electrical connection end 77 may be directly formed on the top surface of the supporting block 50, the fifth electrical connection end 74 is electrically connected with the sixth electrical connection end 77 through the lead 78, and another interconnection structure is arranged in the supporting block 50 and is electrically connected with the sixth electrical connection end 77 and the circuit board 10, so that the circuit board 10 may provide power or signals for the moved element 30. In this embodiment, the flexible connection piece 73 is a flexible interconnection line, and the interconnection structure is a conductive plug. In the present disclosure, the sixth electrical connection end 77 may also be electrically connected with the circuit board 10 through other interconnection modes, for example, the sixth electrical connection end 77 and the circuit board 10 are electrically connected directly through the lead, which is not limited by the present disclosure.

As shown in FIG. 23, the moved element 30 is a reflector. There is one piezoelectric element 20. The movable end of one piezoelectric element 20 is connected with one side of the reflector, and the other opposite side of the reflector is rotatably connected with a supporting surface. When the piezoelectric element 20 is electrified to be warped upwards or downwards, the reflector inclines, thereby changing a reflection angle. In the present disclosure, one side of the reflector is not limited to being provided with one piezoelectric element 20, and may also be provided with two, three, four or five piezoelectric elements. It should be understood that the reflector is not limited to that the piezoelectric element 20 is distributed on only one side of the reflector and the piezoelectric elements 20 may also be distributed at two sides, four sides and circumference of the reflector.

In this embodiment of the present disclosure, one end of the elastic limiting piece is connected to the movable end of the piezoelectric element, and the other end of the elastic limiting piece may be located in the limiting groove and is connected with the rotating shaft stretching into the limiting groove. The transverse movement of the moved element is limited by limiting the movement of the rotating shaft, or one end of the elastic limiting piece is connected to the end part of the movable end and the other end of the elastic limiting piece is connected to a surface opposite to the end part of the movable end, thereby limiting the transverse movement of the moved element. Meanwhile, the elastic limiting piece may limit the movement of the piezoelectric element in the limiting groove, thereby preventing the piezoelectric element from sliding out of the limiting groove and realizing normal work of the piezoelectric element. When the moved element is driven by the piezoelectric element, compared with the traditional driving mechanism such as a VCM motor and the like, the combination of the piezoelectric element and the supporting block is lightweight, small in volume and simple in structure, can realize multi-dimensional motion and is suitable for the imaging module with narrow space volume, and the piezoelectric element is driven by pure voltage without electromagnetic interference. The application range is wider.

It should be noted that each embodiment in the specification is described by a relevant mode, the same or similar part between each embodiment may refer to each other, and each embodiment focuses on the difference from other embodiments. In particular, for the structural embodiment which is basically similar to the method embodiment, the description is relatively simple, and the relevant points are referenced to the partial description of the method embodiment.

The above description is only the description of the preferred embodiment of the present disclosure and does not constitute any limitation to the scope of the present disclosure. Any changes and modifications made by those of ordinary skill in the field of the present disclosure according to the content disclosed above shall fall within the protection scope of the claims.

1. An imaging module, comprising:
a moved element, comprising a lens group, an imaging sensing element, or an aperture, a reflector, or a lens;
a limiting groove, arranged on a surface of the moved element;
a piezoelectric element, comprising a movable end and a fixed end, wherein the movable end is provided with a rotating shaft, the rotating shaft is arranged in the limiting groove, the limiting groove provides a mobile space for the rotating shaft, and the movable end drives the moved element to move upwards or downwards when the piezoelectric element in a power-on state;
an elastic limiting piece, one end of which is connected to the movable end of the piezoelectric element and the other end is located in the limiting groove or connected to a portion opposite to an end face of the movable end, wherein the elastic limiting piece is in a free state when the piezoelectric element is in a free state, and the elastic limiting piece is compressed or stretched when the movable end of the piezoelectric element is warped;
a supporting block, configured to support and fix the piezoelectric element, wherein the fixed end is fixed at the supporting block; and
an external signal connection end, electrically connected to an electrode in the piezoelectric element.

2. The imaging module according to claim 1, wherein an opening direction of the limiting groove faces towards the fixed end of the piezoelectric element, the other end of the elastic limiting piece is connected to an inner wall of the limiting groove, and the elastic limiting piece is stretched when the movable end of the piezoelectric element is warped.

3. The imaging module according to claim 1, wherein an opening direction of the limiting groove departs from the fixed end of the piezoelectric element, the other end of the elastic limiting piece is freely arranged in the limiting groove or connected to an inner wall of the limiting groove, and the elastic limiting piece is compressed when the movable end of the piezoelectric element is warped; and wherein, when the other end of the elastic limiting piece is freely arranged in the limiting groove, the other end is in contact with a side wall of the limiting groove.

4. (canceled)

5. The imaging module according to claim 1, wherein a first film layer, a second film layer and a third film layer which are sequentially stacked are arranged on a surface of the moved element, two sides of the first film layer and the third film layer stretching out relative to the second film layer to form a stretch-out portion, and the limiting groove being surrounded by the stretch-out portion and an end part of the second film layer.

6. The imaging module according to claim 5, wherein one end of the elastic limiting piece is connected to an end part of the movable end of the piezoelectric element, the other end of the elastic limiting piece is connected to an end face of the second film layer opposite to the end part, and the elastic limiting piece is stretched when the movable end of the piezoelectric element is warped.

7. The imaging module according to claim 1, wherein the elastic limiting piece and the rotating shaft have an integrated structure, or the elastic limiting piece and the rotating shaft are connection through an adhesion mode; and wherein the adhesion mode comprises: adhesion through viscose, or adhesion through a dry film.

8. (canceled)

9. The the imaging module according to claim 1, wherein the rotating shafts are distributed on two sides of the movable end;
or at least one of the rotating shafts is distributed between the two sides of the movable end.

10. The imaging module according to claim 1, wherein the limiting groove is surrounded by at least one film layer;

11. The imaging module according to claim 10, wherein the film layer is distributed on an edge of the moved element;
or the film layer is distributed on the whole surface of the moved element.

12. The imaging module according to claim 1, wherein there are at least one pair of piezoelectric elements which are distributed at the periphery of the moved element, the piezoelectric elements in each pair being arranged symmetrically about the moved element; all the piezoelectric elements are located on an upper surface or a lower surface of the moved element; or one of the piezoelectric element is located on the upper surface of the moved element and the other one is located on the lower surface of the moved element.

13. (canceled)

14. (canceled)

15. The imaging module according to claim 1, wherein there are at least one pair of piezoelectric elements which are located in a space below the moved element; the two paired piezoelectric elements are distributed on two sides of a center of the moved element; or the two paired piezoelectric components are arranged in an overlapping manner.

16. (canceled)

17. The imaging module according to claim 15, wherein a fixed position of a supporting wall and the piezoelectric element is located on the space below the moved element or located on an outer side.

18. The imaging module according to claim 1, wherein the moved element comprises a reflector; and the piezoelectric element is distributed on one side of the reflector, and the other opposite side of the reflector is rotatably connected to a supporting surface.

19. The imaging module according to claim 1, wherein the supporting wall is annular;
or the supporting wall comprises a plurality of sub-walls distributed circumferentially, the plurality of sub-walls being spaced apart or in contact with each other.

20. The imaging module according to claim 1, wherein the piezoelectric element is located on a top surface of the supporting wall and/or the supporting wall comprises a first layer of wall and a second layer of wall which are sequentially stacked along a height direction, and the fixed end of the of the piezoelectric element is fixed between the first layer of wall and the second layer of wall; a material of the supporting wall comprises a dielectric material.

21. (canceled)

22. (canceled)

23. The imaging module according to claim 1, when the moved element is an imaging sensing element, the imaging module further comprising a first electrical connection end arranged on the supporting block, wherein an edge of the imaging sensing element is provided with an electrical connection end, and the first electrical connection end and the second electrical connection end are electrically connected through a flexible connection piece.

24. The imaging module according to claim 1, when the moved element is an imaging sensing element, the imaging module further comprising a wiring layer arranged on the piezoelectric element, wherein two ends of the wiring layer are provided with a fifth electrical connection end and a sixth electrical connection end respectively, and an edge of the imaging sensing element is provided with a second electrical connection end;
the first electrical connection end is electrically connected to the fifth electrical connection end through a flexible connection piece; and
the second electrical connection end is electrically connected to the sixth electrical connection end through a flexible connection piece.

25. The imaging module according to claim 1, wherein the piezoelectric element comprises: a supporting layer and a piezoelectric laminated structure located on the supporting layer, the piezoelectric laminated structure comprising: at least one of piezoelectric film, electrodes being distributed on an upper surface and a lower surface of each layer of piezoelectric film, the adjacent two layers of piezoelectric films sharing the electrode located therebetween,
the electrodes being counted sequentially from bottom to top, odd-layer electrodes being electrically connected together, and even-layer electrodes being electrically connected together;
a first leading-out end, electrically connected to the odd-layer electrodes; and a second leading-out end, electrically connected to the even-layer electrodes,
the first leading-out end and the second leading-out end being located on a top surface or a bottom surface of the piezoelectric element, or one of the first leading-out end and the second leading-out end being located on the top surface and the other one being located on the bottom surface.

26. The imaging module according to claim 25, wherein the first leading-out end and the second leading-out end are both located on the top surface of the piezoelectric element and located on a top surface of a supporting wall; and
the first leading-out end and the second leading-out end serve as the external signal connection ends; or the first leading-out end and the second leading-out end are both located between the piezoelectric element and the supporting wall;
the external signal connection ends comprise: a third electrical connection end electrically connected to the first leading-out end, and a fourth electrical connection end electrically connected to the second leading-out end,
the third electrical connection end and the first leading-out end being located on the same side of the piezoelectric element, and
the fourth electrical connection end and the second leading-out end being located on the same side of the piezoelectric element.

27. (canceled)

28. The imaging module according to claim 25, wherein one of the first leading-out end and the second leading-out end is located on the bottom surface of the piezoelectric element, and the other one is located on the top surface of the piezoelectric element and the top surface of the supporting wall; and
the external signal connection ends comprise a third electrical connection end and a fourth electrical connection end, the fourth electrical connection end being located on the bottom surface of the supporting wall and being electrically connected to a leading-out end located on the bottom surface, and a leading-out end located on the top surface of the piezoelectric element serving as the third electrical connection end.

29. (canceled)
